(19) United States
(12) Patent Application Publication
(10) Pub. No.: US 2026/0271629 A1
(43) Pub. Date: Sep. 10, 2026

(54) THREE-DIMENSIONAL INTEGRATED SENSING-MEMORY-COMPUTING CHIP, METHOD FOR MANUFACTURING THE SAME, AND COMPUTING METHOD THEREFOR

(71) Applicant: TSINGHUA UNIVERSITY, Beijing (CN)

(72) Inventors: Lai WANG, Beijing (CN); Wen PAN, Beijing (CN); Jinpu TANG, Beijing (CN); Zhaolong YANG, Beijing (CN); Zhibiao HAO, Beijing (CN); Yi LUO, Beijing (CN)

(73) Assignee: TSINGHUA UNIVERSITY, Beijing (CN)

(21) Appl. No.: 19/667,358

(22) Filed: May 4, 2026

Related U.S. Application Data
(63) Continuation of application No. PCT/CN2026/080263, filed on Feb. 27, 2026.

(30) Foreign Application Priority Data
Feb. 27, 2025 (CN) 202510230953.5

(51) Int. Cl. H10N 70/20; H10B 63/00; H10N 70/00

(52) U.S. Cl. CPC H10N 70/257; H10B 63/30; H10B 63/845; H10N 70/066; H10N 70/24

(57) ABSTRACT

The present application discloses a three-dimensional integrated sensing-memory-computing chip, a method for manufacturing the same, and a computing method therefor, the chip includes sensing-memory-computing units, each includes a stacked resistive random access-memory device, a sensing device, and a gating device; the stacked resistive random access-memory device group includes at least two resistive random access-memory devices formed in a stack in a thickness direction; the sensing device is configured to receive an external signal and convert the external signal into an input signal, and an output end of the sensing device is coupled to a top electrode of the stacked resistive random access-memory device group; and the gating device is configured to receive a control signal and turned on and turned off based on the control signal, and the gating device is coupled to the top electrode of the stacked resistive random access-memory device group.

### CROSS-REFERENCE TO RELATED APPLICATIONS

The present application is a continuation application of International Application No. PCT/CN2026/080263 filed on Feb. 27, 2026, which claims priority to Chinese Patent Application No. 202510230953.5, entitled “THREE-DIMENSIONAL INTEGRATED SENSING-MEMORY-COMPUTING CHIP, METHOD FOR MANUFACTURING THE SAME, AND COMPUTING METHOD THEREFOR” filed on Feb. 27, 2025, both of which are incorporated herein by reference in their entireties.

### TECHNICAL FIELD

The present application relates to the technical field of microelectronic devices, and in particular, to a three-dimensional integrated sensing-memory-computing chip, a method for manufacturing the same, and a computing method therefor.

### BACKGROUND

The sensing function, the memory function and the computing function in a traditional chip are often designed as independent modules. However, this architecture results in high power consumption and high delay in a system and thus is difficult to adapt to increasing requirements on performance of terminal devices.

In view of this, a part of researches proposes that integrating the sensing function, the memory function and the computing function into a single chip achieves optimization of the power consumption and the delay. However, such a chip still have defects of high parasitic capacitance and high dynamic power consumption which need to be optimized.

### SUMMARY

The present application provides a three-dimensional integrated sensing-memory-computing chip, a method for manufacturing a three-dimensional integrated sensing-memory-computing chip, and a computing method for a three-dimensional integrated sensing-memory-computing chip, and one of the purposes is to achieve writing of a plurality of weight values to sensing-memory-computing units by stacking a plurality of resistive random access-memory devices in a thickness direction, and the plurality of resistive random access-memory devices share the top electrode to achieve synchronous storage or synchronous computing, achieving the improvement in chip performance.

In a first aspect, embodiments of the present application provide a three-dimensional integrated sensing-memory-computing chip comprising a sensing-memory-computing unit array provided with a plurality of sensing-memory-computing units, the sensing-memory-computing unit comprises a stacked resistive random access-memory device group, a sensing device and a gating device, the stacked resistive random access-memory device group comprises at least two resistive random access-memory devices formed in a stack in a thickness direction of the three-dimensional integrated sensing-memory-computing chip, the sensing device is configured to receive an external signal and convert the external signal into an input signal, an output end of the sensing device is coupled to a top electrode of the stacked resistive random access-memory device group, and the gating device is configured to receive a control signal and turned on and off based on the control signal, the gating device is coupled to the top electrode of the stacked resistive random access-memory device group, the stacked resistive random access-memory device group is provided between the sensing device and the gating device in a width direction of the three-dimensional integrated sensing-memory-computing chip, and at least two resistive random access-memory devices share the top electrode, so that the at least two of the resistive random access-memory devices synchronously receive the input signal and are synchronously turned on and off.

In some optional embodiments, the stacked resistive random access-memory device group includes the top electrode, a resistive switching layer, and at least two bottom electrodes, the top electrode is coupled to at least two bottom electrodes by the resistive switching layer, and the resistive switching layer is configured to change in a resistance value under control of voltage signals applied to the top electrode and the bottom electrodes.

In some optional embodiments, at least two bottom electrodes are stacked in the thickness direction, an insulation dielectric layer is provided between any two of the bottom electrodes, the top electrode extends at least in the thickness direction to connect the bottom electrodes, and the resistive switching layer extends at least in the thickness direction to space apart the top electrode from each of the bottom electrodes.

In some optional embodiments, the gating device comprises: a substrate; and an active region, a drain, a source, and a gate provided on a side of the substrate, the drain and the source is provided on a side of the active region away from the substrate and electrically isolated by a gate dielectric layer, the gate is provided between the drain and the source in the width direction and spaced apart from the active region by the gate dielectric layer, and the source is electrically connected to the top electrode of the memory device.

In some optional embodiments, the sensing-memory-computing three dimensional integrated chip further includes:
a driving module configured to output the control signal to the gating device;
a bit line extending in a row direction and connected between the driving module and the drain of each of the gating devices; and
a word line extending in a column direction and connected between the driving module and the gate of each of the gating devices.

In some optional embodiments, the sensing-memory-computing three dimensional integrated chip further includes:
a first output wire electrically connected to the stacked resistive random access-memory device group in each of the sensing-memory-computing units; and
a second output wire electrically connected to the sensing device in each of the sensing-memory-computing units.

In some optional embodiments, the sensing device includes a photosensitive layer provided on the side of the active region away from the substrate, and the photosensitive layer and the top electrode of the stacked resistive random access-memory device group are coupled to the active region by the source.

In a second aspect, embodiments of the present application provide a method for manufacturing a three-dimensional integrated sensing-memory-computing chip, the method includes:
providing a gating device and a sensing device;
depositing an insulation dielectric layer and a bottom electrode layer in sequence above the gating device;
repeating the depositing an insulation dielectric layer and a bottom electrode layer until N bottom electrode layers are obtained, wherein an insulating dielectric layer is formed above and below each of the N bottom electrode layers;
etching a stacked structure of the insulation dielectric layer and the bottom electrode layer to form a through via to expose the gating device;
growing a resistive switching layer at an interface of the stacked structure on an inner wall of the through via; and
depositing a top electrode layer on an inner side of the resistive switching layer to complete manufacturing of a stacked resistive random access-memory device group.

In some optional embodiments, a thickness of the insulation dielectric layer is greater than or equal to 100 nm and less than or equal to 300 nm.

In some optional embodiments, a material of the resistive switching layer includes at least one of an oxide, a nitride, a sulfide, or an organic substance, and a thickness of the resistive switching layer is greater than or equal to 4 nm and less than or equal to 30 nm.

In some optional embodiments, a material of the top electrode layer includes an active metal.

In some optional embodiments, a material of the bottom electrode layer includes an inert material.

In a third aspect, embodiments of the present application provide a computing method for a three-dimensional integrated sensing-memory-computing chip, which is applicable to the three-dimensional integrated sensing-memory-computing chip in the first aspect, the computing method includes:
connecting a gating device to a sensing device configured to receive a sample signal and generate a first output current;
disconnecting the sensing device, connecting the gating device to a stacked resistive random access-memory device group, and writing weights to memory devices respectively;
disconnecting the gating device, and connecting the stacked resistive random access-memory device group to the sensing device configured to receive the sample signal and complete a computing based on the weights of the memory devices to generate a second output current; and
comparing the first output current with the second output current, determining whether a target image is a sample image, and completing image recognition.

In the three-dimensional integrated sensing-memory-computing chip provided in an embodiment of the present application, the integration of a plurality of memory devices in the sensing-memory-computing unit is achieved by the form of stacking in the thickness direction. The memory devices use the resistive random access-memory devices to achieve in-memory computing and reduce the signal transmission duration, and the plurality of resistive random access-memory devices share one top electrode to achieve synchronous storage or computing. In the three-dimensional integrated sensing-memory-computing chip, by the form of stacking the memory devices, the memory density is greatly increased, and the performance of the chip in the same area is improved. At the same time, stacking the memory devices reduces the length of the interconnected wires of the devices, reducing the parasitic capacitance and the dynamic power consumption in the sensing-memory-computing unit.

### BRIEF DESCRIPTION OF THE DRAWINGS

Features, advantages and technical effects of exemplary embodiments of the present application will be described below with reference to the drawings.

FIG. 1 is a schematic array diagram of a three-dimensional integrated sensing-memory-computing chip according to some embodiments of the present application;

FIG. 2 is a schematic structural view of a sensing-memory-computing unit according to some embodiments of the present application;

FIG. 3 is a schematic flowchart of a method for manufacturing a three-dimensional integrated sensing-memory-computing chip according to some embodiments of the present application;

FIGS. 4A to 4G are schematic structural views of processes of the method for manufacturing a three-dimensional integrated sensing-memory-computing chip shown in FIG. 3;

FIG. 5 is a schematic flowchart of a computing method for a three-dimensional integrated sensing-memory-computing chip according to some embodiments of the present application; and

FIG. 6 is a schematic sub-flowchart of a computing method for a three-dimensional integrated sensing-memory-computing chip according to some embodiments of the present application.

### REFERENCE NUMERALS

01: Sensing-memory-computing unit;
100: Gating device; 110: Substrate; 121: Epitaxial layer; 1221: First sub-region; 1222: Second sub-region; 131: Drain; 132: Gate; 133: Source; 140: Gate dielectric layer; 150: Isolation structure;
200: Sensing device; 210: Photosensitive layer;
300: Stacked resistive random access-memory device group; 301: Resistive random access-memory device; 310: Top electrode; 320: Resistive switching layer; 331: Bottom electrode; 332: Insulation dielectric layer;
Z: Thickness direction; X: Width direction; Y: Length direction;
WL: Word line; BL: Bit line; C1: First output wire; C2: Second output wire.

### DETAILED DESCRIPTION

In order to make the objects, technical solutions and advantages of the embodiments of the present application clearer, the technical solutions of the embodiments of the present application will be described clearly in conjunction with the drawings in the embodiments of the present application. Obviously, the described embodiments are a part of the embodiments of the present application, but not all of the embodiments. Based on the embodiments in the present application, all other embodiments obtained by those ordinary skilled in the art without any creative work shall fall within the protection scope of the present application.

Unless otherwise defined, all technical and scientific terms used in the present application have the same meanings as commonly understood by those skilled in the technical field of the present application. In the present application, the terms used in the description of the present application are only for purposes of description of specific embodiments, and are not intended to limit the present application. The terms “comprising” and “having” in the description and claims of the present application and the above brief description of the drawings and any variations thereof are intended to cover non-exclusive inclusions. The terms “first”, “second” and the like in the description and claims or the brief description of the drawings of the present application are used to distinguish different objects, rather than to describe a specific order or primary and secondary relationship.

Reference to “an embodiment” in the present application means that a particular feature, structure or characteristic described in conjunction with the embodiment may be included in at least one embodiment of the present application. Appearances of the phrase in various places in the description are not necessarily all referring to the same embodiment, nor a separate or alternative embodiment that is mutually exclusive of other embodiments.

In the description of the present application, it should be noted that, unless otherwise expressly specified and limited, the terms “installed”, “connected”, “connection” and “attached” should be understood in a broad sense, for example, they may refer to a fixed connection, a detachable connection or an integral connection, which may be a direct connection, an indirect connection via an intermediate medium, or an internal communication between two elements. For those of ordinary skill in the art, the specific meanings of the above terms in the present application may be understood in accordance with specific conditions.

In the embodiments of the present application, the same reference numerals represent the same components, and for brevity, in different embodiments, detailed descriptions of the same components are omitted. It should be understood that dimensions, such as thickness, length, width, and the like of various components, as well as overall thickness, length, width, and the like of an integrated device in the embodiments of the present application shown in the drawings are only exemplary descriptions, and should not constitute any limitation to the present application.

The “plurality of” that appears in the present application refers to two or more (including two).

With the rapid development of Internet of Things technology and artificial intelligence technology, the demand of terminal devices for real-time data processing is continuously increasing. The traditional Von Neumann architecture in which memory is separated from computing has defects of low data transferring efficiency and high power consumption, and it is difficult to meet urgent demand of new scenarios such as edge computing for low delay and high energy efficiency.

In recent years, with the development of in-memory computing technology, in a part of researches, integrating sensing-memory-computing functions into a single chip to form a sensing-memory-computing integrated chip effectively reduces the power consumption and the delay, and achieves the improvement in overall performance of a system.

However, the sensing-memory-computing two-dimensional integrated chip is limited by a single chip area, and cannot provide a sufficient memory capacity or computing capability when dealing with complex real-time tasks. Traditional static random access-memory devices, dynamic random access-memory devices, and the like take up a large amount of area, limiting memory density. At the same time, under a two-dimensional structure, continuously increased length and density of interconnected wires result in the increase of the parasitic capacitance and the resistive load, negatively affecting the signal transmission speed and limiting the energy efficiency ratio of the chip.

In view of this, the related research proposes 3-D NAND technology in which a plurality of memory devices are introduced to the sensing-memory-computing chip by the form of vertical stacking to achieve the improvement in the memory and computing capability. However, the form of direct stacking of the memory device and the insulation structure causes the thickness of the chip to be excessively great, so that defects such as warpage easily occurs; meanwhile, the increase in the production cost due to the complexity of the process becomes a hindrance to the large-scale production.

In order to solve the related technical problems, embodiments of the present application provide a three-dimensional integrated sensing-memory-computing chip, a method for manufacturing a three-dimensional integrated sensing-memory-computing chip, and a computing method for a three-dimensional integrated sensing-memory-computing chip. The three-dimensional integrated sensing-memory-computing chip achieves writing of a plurality of weight values to sensing-memory-computing units by stacking a plurality of resistive random access-memory devices in the thickness direction, and the plurality of resistive random access-memory devices share the top electrodes to achieve synchronous storage or synchronous computing, achieving the improvement in chip performance. First, the three-dimensional integrated sensing-memory-computing chip according to the embodiments of the present application will be described below.

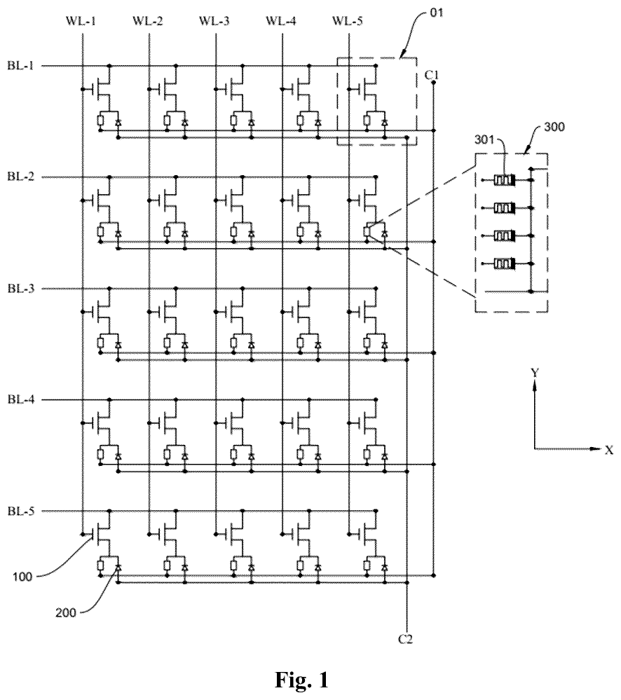

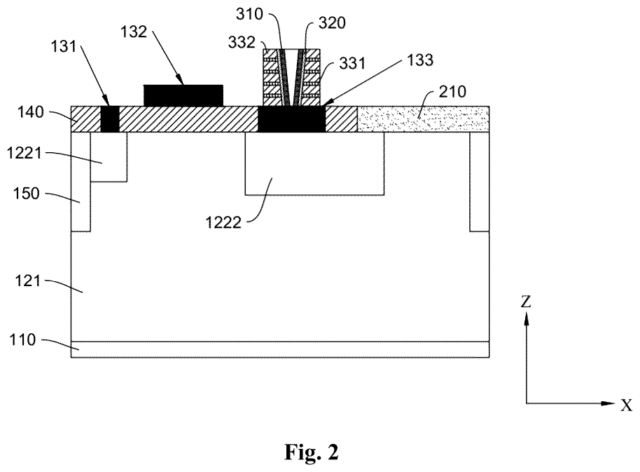

In a first aspect, referring to FIGS. 1 and 2, embodiments of the present application provide a three-dimensional integrated sensing-memory-computing chip including a sensing-memory-computing unit array having a plurality of sensing-memory-computing units 01, the sensing-memory-computing unit 01 includes a stacked resistive random access-memory device group 300, a sensing device 200, and a gating device 100; the stacked resistive random access-memory device group 300 includes at least two resistive random access-memory devices 301 formed in a stack in the thickness direction of the three-dimensional integrated sensing-memory-computing chip; the sensing device 200 is configured to receive the external signal and convert the external signal to the input signal, and the output end of the sensing device 200 is coupled to a top electrode 310 of the stacked resistive random access-memory device group 300; the gating device 100 is configured to receive the control signal and turned on and turned off based on the control signal, and the gating device 100 is coupled to the top electrode 310 of the stacked resistive random access-memory device group 300; the stacked resistive random access-memory device group 300 is provided between the sensing device 200 and the gating device 100 in the width direction of the three-dimensional integrated sensing-memory-computing chip, and at least two resistive random access-memory devices 301 share one top electrode 310, so that the at least two resistive random access-memory devices 301 synchronously receive the input signal or are synchronously turned on and turned off.

As a non-volatile memory device, the resistive random access-memory device 301 can be switched in two ON modes of the high resistance state and the low resistance state in response to voltage stimuli, achieving the integration of the memory function and the computing function. Optionally, the resistive random access-memory device 301 is selected from one of a metal oxide resistive random access-memory device 301, an organic resistive random access-memory device 301, a two-dimensional material resistive random access-memory device 301, an iron resistive random access-memory device 301, a spin resistive random access-memory device 301, and an electrolyte resistive random access-memory device 301.

The sensing device 200 refers to an element which can sense an external physical signal directly on a chip and convert the external physical signal to an electrical signal. The external physical signal includes temperature, light, sound, pressure, and the like. Optionally, the external signal is an optical signal, the input signal is a photocurrent, the sensing device 200 includes a photodiode, and the photodiode is configured to sense the optical signal and convert the optical signal to the electrical signal. Exemplarily, the photodiode is one of a PIN photodiode, a PN junction photodiode, and a Schottky photodiode.

The gating device 100 is an element which controls a current path by turning on and turning off itself to cause a selected sensing-memory-computing unit 01 to be activated. Optionally, the gating device 100 uses one of a metal semiconductor field effect transistor, a magnetoresistive tunnel junction, a diode, a threshold switch, and a two-terminal gating device 100. Exemplarily, the gating device 100 uses a metal semiconductor field effect transistor. In some embodiments, in order to reduce the power consumption of the system, the metal semiconductor field effect transistor is designed to have a low threshold voltage for driving. For example, the threshold voltage is not greater than 5 V.

Therefore, the three-dimensional integrated sensing-memory-computing chip achieves monolithic integration of a plurality of memories by stacking in the thickness direction, so that the writing of the plurality of weight values is achieved, and the memory density of the three-dimensional integrated sensing-memory-computing chip is increased. The three-dimensional integrated sensing-memory-computing chip uses the electrolyte resistive random access-memory device 301 to achieve the in-memory computing, so that the signal transmission duration can be reduced, and the signal transmission speed can be increased. The plurality of resistive random access-memory devices 301 share the top electrode 310, so that the plurality of resistive random access-memory devices 301 can synchronously perform the operation of weight writing or computing. Therefore, the real-time data processing capability of the chip within the same area is further improved, the thickness of the chip is greatly reduced compared with the form of direct stacking, and process simplification and cost optimization are achieved, which has greater potential for the large-scale production. Further, compared with a planar chip with the same computing capability, the stacking form of the three-dimensional integrated sensing-memory-computing chip reduces the length of the interconnected wires in the chip, so that the dynamic power consumption and the parasitic capacitance in the chip are reduced, achieving performance optimization.

According to some embodiments of the present application, the stacked resistive random access-memory device group 300 includes the top electrode 310, a resistive switching layer 320, and at least two bottom electrodes 331, the top electrode 310 is coupled to the at least two bottom electrodes 331 by the resistive switching layer 320, and the resistive switching layer 320 is configured to change in the resistance value under the control of the voltage signal applied to the top electrode 310 and the bottom electrodes 331.

It may be understood that the voltage stimuli may be separately applied to the at least two bottom electrodes 331 to achieve independent weight writing and subsequent computing operations under a condition that the top electrode 310 is shared.

Optionally, the thickness of the resistive switching layer 320 is greater than or equal to 4 nm. It may be understood that the thickness direction of the resistive switching layer 320 is different from the thickness direction of the three-dimensional integrated sensing-memory-computing chip. Specifically, the thickness direction of the resistive switching layer 320 refers to the direction perpendicular to both the contact surface of the top electrode 310 and the resistive switching layer 320 and the contact surface of the bottom electrode 331 and the resistive switching layer 320.

Further, optionally, the thickness of the resistive switching layer 320 is less than or equal to 30 nm.

Optionally, the resistive switching layer 320 is made of at least one of a metal oxide, a chalcogenide, a perovskite material, an organic material, or a nitride. The metal oxide includes hafnium oxide, tantalum pentoxide, titanium dioxide, bismuth ferrite, and the like. Exemplarily, the resistive switching layer 320 is made of hafnium oxide.

Therefore, under a condition that the sensing-memory-computing unit 01 performs the weight writing or calculating operations, the top electrode 310 responds to the control signal of the gating device 100 or the input signal of the sensing device 200, so that the plurality of resistive random access-memory devices 301 synchronously receive the voltage signal stimuli of the top electrode 310, and perform the weight writing or calculating operations, respectively, to achieve the memory function or the calculating function.

According to some embodiments of the present application, the at least two bottom electrodes 331 are stacked in the thickness direction, the insulation dielectric layer 332 is provided between any two bottom electrodes 331, the top electrode 310 extends at least in the thickness direction to connect the bottom electrodes 331, and the resistive switching layer 320 extends at least in the thickness direction to space apart the top electrode 310 from the bottom electrodes 331. Optionally, the resistive switching layer 320 may be inclined relative to the thickness direction, and therefore it facilitates processing on the inner wall of the through via formed by etching and also can provide a basis that facilitates adhesion for subsequent manufacturing of the top electrode 310.

Optionally, the top electrode 310 may be inclined relative to the thickness direction to facilitate processing and manufacturing by the form such as deposition and coupling to each of the bottom electrodes 331.

It may be understood that the insulation dielectric layer 332 is configured to block the lateral leakage current between adjacent two bottom electrodes 331 in the thickness direction. The insulation dielectric layer 332 can form device isolation between the resistive random access-memory devices 301, so that the resistive random access-memory devices 301 can be independently controlled to be turned on and turned off by adjusting the voltage of the bottom electrodes 331.

Optionally, the thickness of the insulation dielectric layer 332 is greater than or equal to 100 nm. The thickness of the insulation dielectric layer 332 refers to the minimum length of the insulation dielectric layer 332 in the thickness direction of the three-dimensional integrated sensing-memory-computing chip.

Further, optionally, the thickness of the insulation dielectric layer 332 is less than or equal to 300 nm.

Optionally, the top electrode 310 is made of an active metal material, and the bottom electrode 331 is made of an inert material.

Therefore, a plurality of bottom electrodes 331 stacked in the thickness direction can form a plurality of resistive random access-memory devices 301 by sharing the resistive switching layer 320 and the top electrode 310, so that the thickness of the chip is controlled while the memory density of the sensing-memory-computing unit 01 is increased, and the thermal management of the chip is facilitated while the parasitic capacitance is reduced.

According to some embodiments of the present application, the gating device 100 includes a substrate 110, an active region, an drain 131, a source 133, and a gate 132 provided on a side of the substrate 110, the drain 131 and the source 133 are provided on a side of the active region away from the substrate 110 and are electrically isolated by the gate dielectric layer 140, the gate 132 is provided between the drain 131 and the source 133 in the width direction and is spaced apart from the active region by the gate dielectric layer 140, and the source 133 is electrically connected to the top electrode 310 of the memory device.

Optionally, the drain 131 and the gate 132 of the gating device 100 are provided with a row gating signal and a column gating signal, respectively, so that the chip can select the target sensing-memory-computing unit 01 based on the row gating signal and the column gating signal and perform operations such as weight writing, computing, or image collection.

Specifically, the active region includes an epitaxial layer 121 doped with a first conductive type ions and a well region provided within the epitaxial layer 121 and doped with a second conductive type ions. Exemplarily, the first conductive type is P-type, and the second conductive type is N-type.

Optionally, the well region includes a first sub-region 1221 coupled to the drain 131 and a second sub-region 1222 coupled to the source 133. Exemplarily, an orthographic projection of the drain 131 on the substrate 110 falls within an orthographic projection of the first sub-region 1221 on the substrate 110, and an orthographic projection of the source 133 on the substrate 110 falls within an orthographic projection of the second sub-region 1222 on the substrate 110.

Further, optionally, the doping concentration of the second sub-region 1222 is greater than the doping concentration of the first sub-region 1221, or the doping concentration of the second sub-region 1222 is equal to the doping concentration of the first sub-region 1221.

Further, optionally, the orthographic projection of the top electrode 310 on the substrate 110 falls within the orthographic projection of the source 133 on the substrate 110.

Still further, optionally, an orthographic projection of the stacked resistive random access-memory device group 300 on the substrate 110 falls within the orthographic projection of the source 133 on the substrate 110.

It may be understood that an insulation dielectric layer 332 is provided between the stacked resistive random access-memory device group 300 and the source 133 to achieve electrical isolation between the bottom electrode 331 of the resistive random access-memory region and the source 133 of the gating device 100.

It may be understood that the gating device 100 further includes an isolation structure 150 provided on the periphery in the horizontal plane to achieve electrical isolation between different sensing-memory-computing units 01, achieving gating or turning off of the target sensing-memory-computing unit 01. Specifically, the isolation structures 150 are provided on two sides of the active region in the width direction of the three-dimensional integrated sensing-memory-computing chip, and the isolation structures 150 are further provided on two sides of the active region in the length direction of the three-dimensional integrated sensing-memory-computing chip.

Therefore, the gating device 100 is a transistor, and under a condition that the drain 131 and the gate 132 of the transistor sense the control signal, the sensing-memory-computing unit 01 where the transistor is located is tuned on to perform operations such as image collection, weight writing, or computing, and the three-dimensional integrated sensing-memory-computing chip achieves calling of different sensing-memory-computing units 01 by the gating device 100.

According to some embodiments of the present application, the three-dimensional integrated sensing-memory-computing chip further includes:
a driving module, configured to output a control signal to the gating device 100;
a bit line extending in the row direction and connected between the driving module and the drain 131 of each of the gating devices 100; and
a word line extending in the column direction and connected between the driving module and the gate 132 of each of the gating devices 100.

Optionally, the driving module includes a word line driving unit and a bit line driving unit, the word line driving unit is connected to the gate 132 of each of the gating devices 100 by the word line, and the bit line driving unit is connected to the drain 131 of each of the gating devices 100 by the bit line.

Optionally, the width direction of the three-dimensional integrated sensing-memory-computing chip is the row direction, the length direction of the three-dimensional integrated sensing-memory-computing chip is the column direction, and the plurality of sensing-memory-computing units 01 are provided in a matrix array.

Exemplarily, the sensing-memory-computing units 01 are in the number of xy, and xy sensing-memory-computing units 01 are distributed in x rows and y columns; the bit lines are in the number of x, and x bit lines are electrically connected to x rows of sensing-memory-computing units 01, respectively; the word lines are in the number of y, and y bit lines are electrically connected to y rows of sensing-memory-computing units 01, respectively. The bit line is configured to control the turned-on state of the drains 131 of y sensing-memory-computing units 01 in the same row, and the word line is configured to control the turned-on state of the gates 132 of x sensing-memory-computing units 01 in the same column.

Optionally, the gating device 100 includes a passivation layer covering above the drain 131 and the gate 132, the passivation layer above the drain 131 is provided with a first via, in which the first conductive metal is deposited to form the bit line; the passivation layer above the gate 132 is provided with a second via, in which the second conductive metal is deposited to form the word line. In the thickness direction of the three-dimensional integrated sensing-memory-computing chip, the word line and the bit line are insulated and separated by the passivation layer.

Therefore, the driving module can transmit the control signal via the word line and the bit line and select the corresponding sensing-memory-computing unit 01 to be turned on, achieving operations such as image collection, weight writing, or computing.

According to some embodiments of the present application, the three-dimensional integrated sensing-memory-computing chip further includes:
a first output wire electrically connected to the stacked resistive random access-memory device group 300 in each of the sensing-memory-computing units 01;
a second output wire electrically connected to the sensing device 200 in each of the sensing-memory-computing units 01.

Optionally, the first output wire includes at least two writing sub-wires, and the at least two writing sub-wires are connected to the bottom electrodes 331 of at least two resistive random access-memory devices 301 in each of the sensing-memory-computing units 01 in a one-to-one correspondence to perform the weight writing operation on the resistive random access-memory devices 301 in the same sensing-memory-computing unit 01, respectively.

Exemplarily, the stacked resistive random access-memory device group 300 includes two resistive random access-memory devices 301, the first output wire includes two writing sub-wires, one of the writing sub-wires is electrically connected to the bottom electrode 331 in each of the sensing-memory-computing units 01 on a side close to the active region, and the other of the writing sub-wires is electrically connected to the bottom electrode 331 in each of the sensing-memory-computing units 01 on a side away from the active region.

Optionally, the three-dimensional integrated sensing-memory-computing chip further includes a first inverting amplifier connected to the output end of the first output wire and configured to generate the first output voltage as the computing result.

Optionally, the three-dimensional integrated sensing-memory-computing chip further includes a second inverting amplifier connected to the output end of the second output wire and configured to generate the second output voltage as the image collection result. The three-dimensional integrated sensing-memory-computing chip can complete the image recognition task by comparing the first output voltage with the second output voltage.

Therefore, the three-dimensional integrated sensing-memory-computing chip can output the total currents as the collection result and the computing result in the collection mode and the computing mode, respectively, and complete the recognition task based on the comparison between the computing result and the collection result. It may be understood that the recognition task may be a task such as image recognition and speech recognition.

According to some embodiments of the present application, the sensing device 200 includes a photosensitive layer 210 provided on a side of the active region away from the substrate 110, and the photosensitive layer 210 and the top electrode 310 of the stacked resistive random access-memory device group 300 are coupled to the active region by the source 133.

Optionally, an orthographic projection of at least a part of the photosensitive layer 210 on the substrate 110 falls within an orthographic projection of the second sub-region 1222 on the substrate 110.

Further, optionally, an orthographic projection of the photosensitive layer 210 on the substrate 110 falls within the orthographic projection of the second sub-region 1222 on the substrate 110.

Optionally, the photosensitive layer 210 is adjacent to the source 133 of the gating device 100 in the width direction of the three-dimensional integrated sensing-memory-computing chip, or the photosensitive layer 210 is spaced apart from the source 133 of the gating device 100 in the width direction of the three-dimensional integrated sensing-memory-computing chip and separated from the source 133 of the gating device 100 by the gate dielectric layer 140.

Optionally, the photosensitive layer 210 is made of at least one of silicon, gallium arsenide, indium phosphide, HgCdTe (MCT), or an organic semiconductor material.

Therefore, the sensing device 200 can receive the external optical signal and generate the photocurrent. The photocurrent can directly output the image collection result by the second output wire; or the photocurrent can be transmitted to the top electrode 310 of the stacked resistive random access-memory device group 300 by the second sub-region 1222 and the source 133, and the computing result is output by the resistive random access-memory devices 301 and the first output wire.

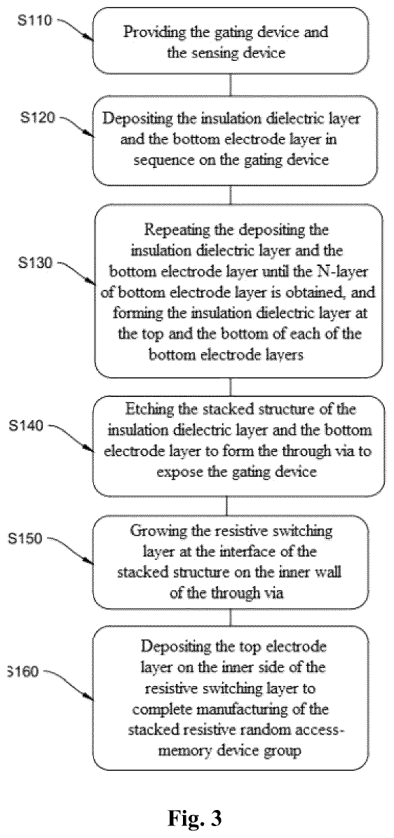

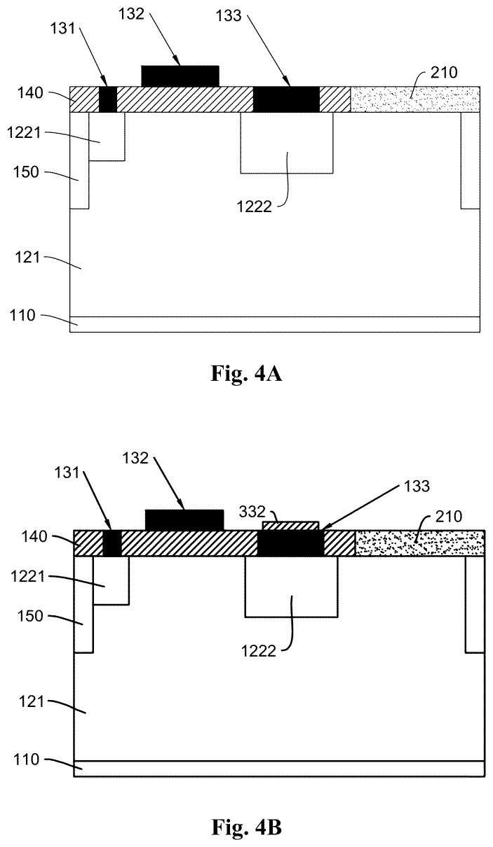

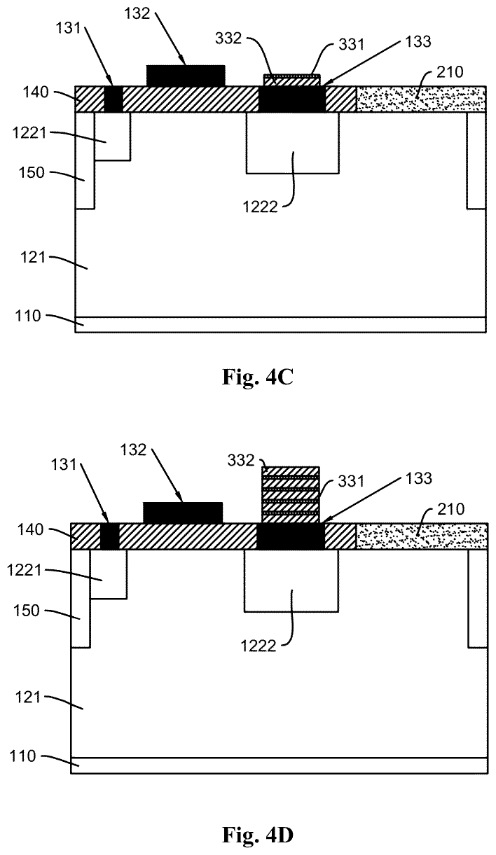

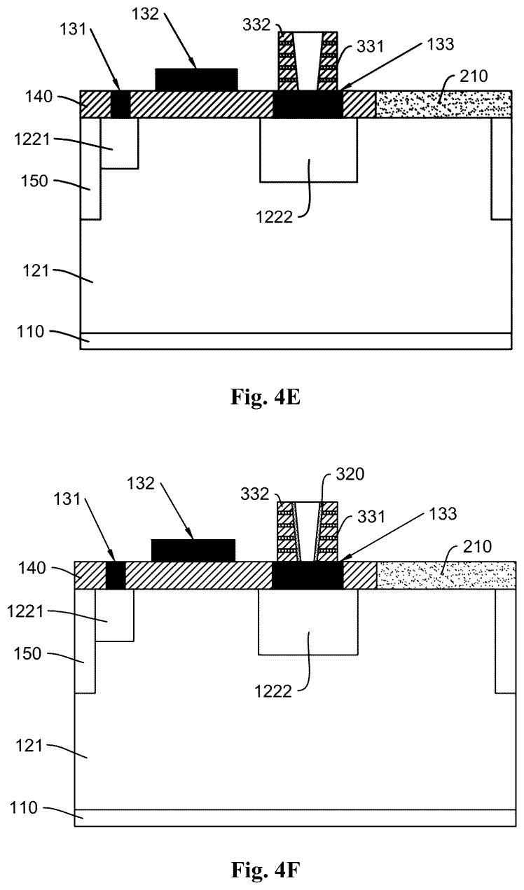

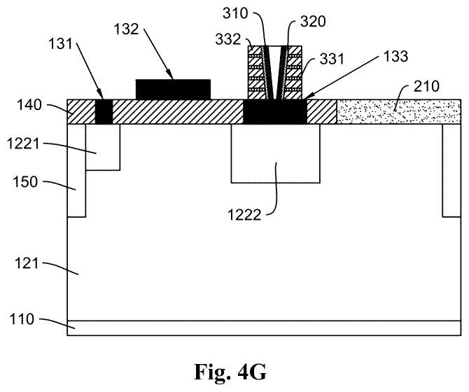

In a second aspect, referring to FIGS. 3 and 4A to 4G, embodiments of the present application provide a method for manufacturing a three-dimensional integrated sensing-memory-computing chip, and the method for manufacturing a three-dimensional integrated sensing-memory-computing chip includes:
S110, providing a gating device and a sensing device;
S120, depositing an insulation dielectric layer and a bottom electrode layer in sequence on the gating device;
S130, repeating the depositing an insulation dielectric layer and a bottom electrode layer until N bottom electrode layers are obtained, an insulating dielectric layer is formed above and below each of the N bottom electrode layers;
S140, etching a stacked structure of the insulation dielectric layer and the bottom electrode layer to form a through via to expose the gating device;
S150, growing a resistive switching layer at the interface of the stacked structure on the inner wall of the through via; and
S160, depositing a top electrode layer on the inner side of the resistive switching layer to complete manufacturing of the stacked resistive random access-memory device group.

Therefore, compared with the traditional three-dimensional integrated chip formed by stacked memory devices, in the present application, the number of the stacked layers is greatly reduced, improving the manufacturability of the chip. For example, taking an example of manufacturing a two-layer resistive random access-memory device, in the related art, three insulation layers, two top electrode layers, two bottom electrode layers, and two resistive switching layers need to be manufactured; in the method for manufacturing a three-dimensional integrated sensing-memory-computing chip according to the present application, three insulation layers, two bottom electrode layers, one top electrode layer, and one resistive switching layer need to be manufactured, neither the top electrode layer nor the resistive switching layer occupies a space in the thickness direction of the chip, and this advantage will be more prominent with the increase of the stacking number of the resistive random access-memory devices.

According to some embodiments of the present application, step S110 includes:
S111, providing a substrate, and growing an epitaxial layer on a side of the substrate;
S112, implanting a first conductive type ions into the epitaxial layer;
S113, implanting a second conductive type ions into a surface of the epitaxial layer away from the substrate to form a well region located in the epitaxial layer;
S114, forming a source and a drain on the surface of the epitaxial layer away from the substrate;
S115, forming a gate dielectric layer on the surface of the epitaxial layer away from the substrate; and
S116, forming the gate on the surface of the gate dielectric layer away from the substrate.

Optionally, step S110 further includes:
S117, etching the gate dielectric layer to expose the second sub-region; and
S118, depositing and forming a photosensitive layer above the second sub-region.

Optionally, in step S114, the source and the drain are manufactured by the deposition process.

Further, optionally, in step S114, the surface of the epitaxial layer away from the substrate is provided with a mask, and the source and the drain are directly deposited.

Optionally, in step S116, the gate is manufactured by the deposition process.

Further, optionally, in step S116, the surface of the gate dielectric layer away from the substrate is provided with a mask, and the gate is directly deposited.

According to some embodiments of the present application, in step S120, the insulation dielectric layer and the bottom electrode layer are formed using a same mask.

According to some embodiments of the present application, in step S120 and step S130, the thickness of the insulation dielectric layer is greater than or equal to 100 nm and less than or equal to 300 nm.

Optionally, the material of the insulation dielectric layer includes at least one of silicon dioxide, silicon nitride, or a polymer insulation material.

According to some embodiments of the present application, in step S120 and step S130, the material of the bottom electrode layer includes an inert material.

Exemplarily, the material of the bottom electrode layer includes at least one of gold, platinum, or titanium nitride.

According to some embodiments of the present application, in step S140, the through via formed by etching is an inverted cone-shaped structure. Specifically, referring to FIG. 4E, in the width direction of the three-dimensional integrated sensing-memory-computing chip, the size of the opening of the through via on a side away from the substrate is greater than the size of the opening on a side close to the substrate, so as to facilitate the subsequent process of growing the resistive switching layer on the inner wall of the through via and depositing the top electrode layer.

Optionally, in step S140, a mask is provided, and the stacked structure of the insulation dielectric layer and the bottom electrode layer is etched to form the through via and expose the source.

Further, optionally, the through via is formed at the center position of the stacked structure of the insulation dielectric layer and the bottom electrode layer.

According to some embodiments of the present application, in step S150, the material of the resistive switching layer includes at least one of an oxide, a nitride, a sulfide, or an organic substance.

Optionally, the thickness of the resistive switching layer is greater than or equal to 4 nm and less than or equal to 30 nm.

Exemplarily, the resistive switching layer is a hafnium oxide layer.

It may be understood that, between adjacent two bottom electrodes, one or more resistive switching layers may be provided. Under a condition that a plurality of resistive switching layers are provided, the materials of directly adjacent two resistive switching layers are different from each other.

According to some embodiments of the present application, in step S160, the material of the top electrode layer includes an active metal.

Exemplarily, the material of the top electrode layer includes one of copper, silver, lead.

According to some embodiments of the present disclosure, the method for manufacturing a three-dimensional integrated sensing-memory-computing chip further includes:
S171, manufacturing a passivation layer above the gate;
S172, etching the passivation layer to form a first through via to expose the drain, and depositing a first conductive metal in the first through via to obtain a bit line; and
S173, etching the passivation layer to form a second through via to expose the gate, and depositing a second conductive metal in the second through via to obtain a word line.

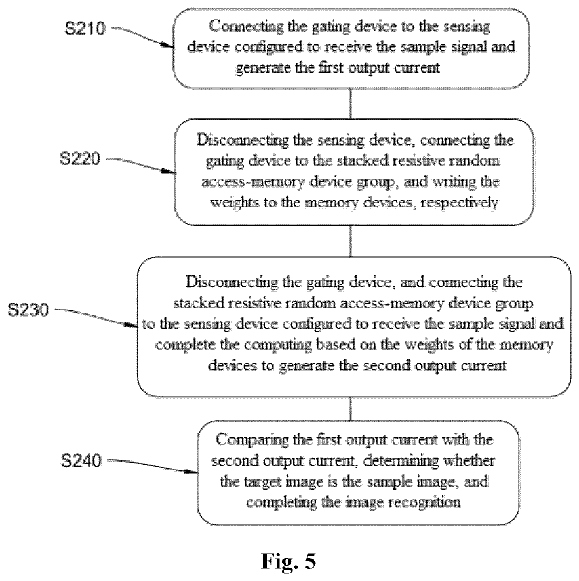

In a third aspect, referring to FIG. 5, embodiments of the present application provide a computing method for a three-dimensional integrated sensing-memory-computing chip, which is applicable to the three-dimensional integrated sensing-memory-computing chip according to any one of the embodiments of the first aspect, and the computing method for a three-dimensional integrated sensing-memory-computing chip method includes:
S210, connecting a gating device to a sensing device configured to receive a sample signal and generate a first output current;
S220, disconnecting the sensing device, connecting the gating device to a stacked resistive random access-memory device group, and writing weights to memory devices, respectively;
S230, disconnecting the gating device, and connecting the stacked resistive random access-memory device group to the sensing device configured to receive the sample signal and complete the computing based on the weights of the memory devices to generate a second output current; and
S240, completing the image recognition by comparing the first output current with the second output current to determine whether a target image is the sample image.

According to some embodiments of the present application, step S210 includes:
S211, providing a first voltage to the j-th column of word line, and providing a second voltage less than the first voltage to the i-th row of bit line or grounding the i-th row of bit line; and
S212, providing a read signal to a second output wire.

Therefore, the selection and reading of the single sensing-memory-computing unit of the i-th row and the j-th column is achieved.

According to some embodiments of the present application, step S220 includes:
S221, providing voltages to the bottom electrodes of the resistive random access-memory devices by the writing sub-wire, respectively;
S222, providing the third voltage to the j-th column word line, and providing the writing signal or the rewriting signal to the i-th row bit line; and
S223, providing the read signal to the first output wire.

Therefore, the selection of and the writing of weights to the single sensing-memory-computing unit of the i-th row and the j-th column are achieved. Each of the bottom electrodes to which the voltage stimulus is applied is turned on at the same time after the sensing-memory-computing unit is selected, so that the weight writing operation can be performed at the same time.

Optionally, in step S221, the driving module is configured to divide the system clock into N sub-periods by a time slice distribution circuit, each of the sub-periods corresponds to the weight writing of one layer of resistive random access-memory device, and the writing voltages are loaded to the bottom electrodes in sequence by the writing sub-wire.

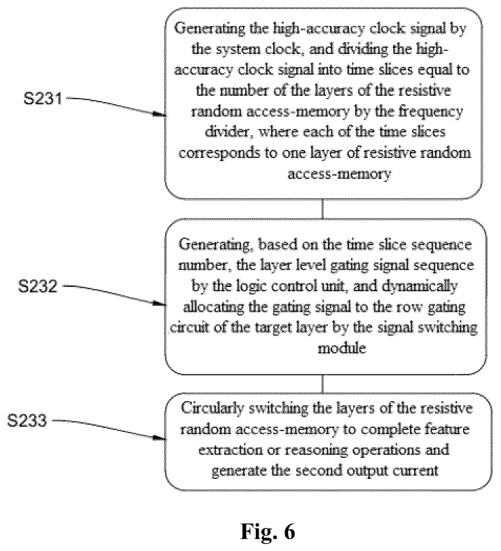

According to some embodiments of the present application, referring to FIG. 6, step S230 includes:
S231, generating a high-accuracy clock signal by the system clock, and dividing the high-accuracy clock signal into time slices corresponding to the number of the layers of the resistive random access-memory device 301 by the frequency divider, each of the time slices corresponds to one layer of resistive random access-memory device;
S232, generating, based on the time slice sequence number, a layer level gating signal sequence by a logic control unit, and dynamically allocating the gating signal to the row gating circuit of the target layer by a signal switching module; and
S233, circularly switching the layers of the resistive random access-memory device to complete feature extraction or reasoning operations and generate the second output current.

Specifically, in step S233, the second output current is the accumulated value of the output current of each of the sensing-memory-computing units in the array, and the output current of each of the sensing-memory-computing units is the accumulated value of the output current of each layer of resistive random access-memory in the unit. The output current of a single resistive random access-memory is the product of the weight of the single resistive random access-memory and the photocurrent. Therefore, the second output current is calculated by the coupling of the sensing-memory-computing unit to the photocurrent and can characterize the target image.

According to some embodiments of the present application, step S240 includes:
S241, obtaining a first output voltage and a second output voltage based on the first output current and the second output current; and
S242, performing a normalization process on the first output voltage and the second output voltage to obtain a computing result, and comparing the computing result with a pre-set threshold to determine whether a target image is the sample image.

Optionally, in step S241, the first output voltage and the second output voltage are obtained by performing the inverse amplification operation on the first output current and the second output current by the operational amplifier.

Although the present application has been described with reference to the preferred embodiments, various improvements may be made thereto and components thereof may be replaced with equivalents without departing from the scope of the present application. In particular, various technical features described in various embodiments may be combined in any manner as long as there is no structural conflict. The present application is not limited to the specific embodiments described herein, and includes all technical solutions that fall within the scope of the claims.

What is claimed is:

1. A three-dimensional integrated sensing-memory-computing chip, comprising a sensing-memory-computing unit array including a plurality of sensing-memory-computing units, each of which comprises:
a stacked resistive random access-memory device group comprising at least two resistive random access-memory devices stacked in a thickness direction of the three-dimensional integrated sensing-memory-computing chip;
a sensing device configured to receive an external signal and convert the external signal into an input signal, an output end of the sensing device being coupled to a top electrode of the stacked resistive random access-memory device group; and
a gating device configured to receive a control signal to turned on or off based on the control signal, the gating device being coupled to the top electrode of the stacked resistive random access-memory device group,
wherein the stacked resistive random access-memory device group is provided between the sensing device and the gating device in a width direction of the three-dimensional integrated sensing-memory-computing chip, and the at least two resistive random access-memory devices share the top electrode, so that the at least two resistive random access-memory devices synchronously receive the input signal and are synchronously turned on and off.

2. The three-dimensional integrated sensing-memory-computing chip according to claim 1, wherein the stacked resistive random access-memory device group comprises the top electrode, a resistive switching layer, and at least two bottom electrodes, the top electrode being coupled to the at least two bottom electrodes by the resistive switching layer, and the resistive switching layer being configured to change a resistance value thereof under control of voltage signals applied to the top electrode and the bottom electrodes.

3. The three-dimensional integrated sensing-memory-computing chip according to claim 2, wherein the at least two bottom electrodes are stacked in the thickness direction, an insulation dielectric layer is provided between any two of the bottom electrodes, the top electrode extends in at least the thickness direction to connect each of the bottom electrodes, and the resistive switching layer extends in at least the thickness direction to space apart the top electrode from each of the bottom electrodes.

4. The three-dimensional integrated sensing-memory-computing chip according to claim 1, wherein the gating device comprises:
a substrate; and
an active region, a drain, a source, and a gate provided on a side of the substrate, the drain and the source being provided on a side of the active region away from the substrate and electrically isolated by a gate dielectric layer, the gate being provided between the drain and the source in the width direction and spaced apart from the active region by the gate dielectric layer, and the source being electrically connected to the top electrode of the stacked resistive random access-memory device group.

5. The three-dimensional integrated sensing-memory-computing chip according to claim 4, further comprising:
a driving module configured to output the control signal to the gating device;
a bit line extending in a row direction and connected between the driving module and the drain of the gating device; and
a word line extending in a column direction and connected between the driving module and the gate of the gating device.

6. The three-dimensional integrated sensing-memory-computing chip according to claim 5, further comprising:
a first output wire electrically connected to the stacked resistive random access-memory device group of each of the sensing-memory-computing units; and
a second output wire electrically connected to the sensing device of each of the sensing-memory-computing units.

7. The three-dimensional integrated sensing-memory-computing chip according to claim 4, wherein the sensing device comprises a photosensitive layer provided on the side of the active region away from the substrate, and the photosensitive layer and the top electrode of the stacked resistive random access-memory device group are coupled to the active region by the source.

8. A method for manufacturing a three-dimensional integrated sensing-memory-computing chip, comprising:
providing a gating device and a sensing device;
depositing an insulation dielectric layer and a bottom electrode layer in sequence above the gating device;
repeating the depositing an insulation dielectric layer and a bottom electrode layer until N bottom electrode layers are obtained, wherein each of the N bottom electrode layers is between two of the insulating dielectric layers;
etching a stacked structure of the insulation dielectric layers and the bottom electrode layers to form a through via to expose the gating device;
growing a resistive switching layer at an interface of the stacked structure on an inner wall of the through via; and
depositing a top electrode layer on an inner side of the resistive switching layer to complete manufacturing of a stacked resistive random access-memory device group.

9. The method for manufacturing a three-dimensional integrated sensing-memory-computing chip according to claim 8, wherein a thickness of the insulation dielectric layer is greater than or equal to 100 nm and less than or equal to 300 nm; and/or
a material of the resistive switching layer comprises at least one of an oxide, a nitride, a sulfide, or an organic substance, and a thickness of the resistive switching layer is greater than or equal to 4 nm and less than or equal to 30 nm; and/or
a material of the top electrode layer comprises an active metal; and/or
a material of the bottom electrode layer comprises an inert material.

10. A computing method for a three-dimensional integrated sensing-memory-computing chip, which is applicable to the three-dimensional integrated sensing-memory-computing chip according to claim 1, the computing method comprising:
connecting a gating device to a sensing device to cause the sensing device to receive a sample signal and generate a first output current;
disconnecting the sensing device from the gating device, and connecting the gating device to a stacked resistive random access-memory device group to write weights to memory devices respectively;
disconnecting the gating device from the sensing device, and connecting the stacked resistive random access-memory device group to the sensing device to cause the sensing device to receive the sample signal and complete computing based on the weights of the memory devices to generate a second output current; and
completing image recognition by comparing the first output current with the second output current and determining whether a target image is a sample image, and.
